(19) United States
(12) Patent Application Publication
(10) Pub. No.: US 2021/0404059 A1
(43) Pub. Date: Dec. 30, 2021

(54) PROCESSING SYSTEM AND METHOD OF CONTROLLING CONDUCTANCE IN A PROCESSING SYSTEM

(71) Applicant: Applied Materials, Inc., Santa Clara, CA (US)

(72) Inventors: Muhammad M. RASHEED, San Jose, CA (US); Anqing CUI, Santa Clara (US)

(21) Appl. No.: 17/003,622

(22) Filed: Aug. 26, 2020

Related U.S. Application Data
(60) Provisional application No. 63/044,916, filed on Jun. 26, 2020.

(51) Int. Cl. C23C 16/455; C23C 16/52

(52) U.S. Cl. CPC C23C 16/45527; C23C 16/52; C23C 16/45544

(57) ABSTRACT

Embodiments provided herein generally relate to a processing system and a method of controlling conductance in a processing system. The processing system and method disclosed herein allow for control of gas ratios within the processing system, while still maintaining a high level of conductance. The processing system includes a purge gas valve configured to pulse a flow of foreline purge gas. The method includes pulsing the foreline purge gas. The method is contained in a computer readable medium. The pulsed foreline purge gas can maintain a ratio of process purge gas and the process gas in the processing region.

### CROSS-REFERENCE TO RELATED APPLICATIONS

This application claims priority to U.S. Provisional Patent Application No. 63/044,916, filed Jun. 26, 2020, which is herein incorporated by reference in its entirety.

### BACKGROUND

### Field

Embodiments of the invention relate to an apparatus and a method and, more specifically, to a processing system and a method of controlling conductance in a processing system.

### Description of the Related Art

Atomic layer deposition (ALD) is a thin-film deposition technique based on a sequential gas phase chemical process. The majority of ALD reactions use two chemicals called precursors. These precursors react with the surface of a material one at a time in a sequential, self-limiting, manner. Through the repeated exposure to separate precursors, a thin film is slowly deposited. ALD is a key process in the fabrication of semiconductor devices, and part of the set of tools available for the synthesis of nanomaterials.

In ALD, the growth progresses layer by layer by alternatively pulsing the source gases. This enables ultra-fine thickness control of the growth of the film layers. In most other chemical vapor deposition (CVD) techniques, all source gases flow simultaneously and some energy source is provided to aid the reaction (high-temperature or plasma). In cases where fine control of layer growth is needed, ALD is preferred over CVD. For ALD chambers, it is desired to have a high exchange rate of gas to prevent the CVD reaction. Gas exchange rate depends on pumping conductance of the chamber and its exhaust. Therefore, it is desired to have a high conductance of process and other gases in the processing region, which encourages ALD growth and discourages CVD growth.

One drawback in the art is that it can be difficult to maintain proper ratios of carrier and process gases in the processing region, which is important for proper ALD film growth. In addition, control of conductance in the processing region of conventional chambers can be difficult to maintain while still resulting in a high throughput of film growth. Also, conventional processing chambers cannot always reliably control ALD growth in contrast to CVD growth.

Therefore, there is a need for chambers that allow for gas conductance control.

### SUMMARY

Embodiments provided herein generally relate to a processing system and a method of controlling conductance in a processing system. The processing system and method disclosed herein allows for control of gas ratios within the processing system, while still maintaining a high level of conductance.

In one embodiment, a method of controlling conductance in a processing region of a processing chamber is provided. The method includes supplying a process gas into the processing chamber through a process gas intake, supplying a foreline purge gas into a foreline, and pulsing the foreline purge gas into the foreline.

In another embodiment, a processing system is provided. The processing system includes a processing apparatus and a controller. The processing apparatus includes a processing chamber and an outtake system. The processing chamber includes a chamber body defining a processing region. The outtake system includes a foreline fluidly coupled to the chamber body, a foreline purge gas line fluidly coupled to the foreline, a foreline purge gas source fluidly coupled to the foreline purge gas line, and a foreline purge gas valve disposed in the foreline purge gas line. The controller is coupled to the foreline purge gas valve. The controller is configured to perform a method of controlling conductance in the processing region of the processing chamber. The method includes supplying a process gas into the processing chamber, supplying a foreline purge gas into the foreline, and pulsing the foreline purge gas into the foreline. The pulsing the foreline purge gas includes alternately opening and closing the foreline purge gas valve.

In yet another embodiment, a non-transient computer readable medium is provided. The non-transient computer readable medium contains program instructions for causing a controller to perform a method. The method includes supplying a process gas into a processing region of a processing chamber, supplying a foreline purge gas into the foreline, and pulsing the foreline purge gas into the foreline.

### BRIEF DESCRIPTION OF THE DRAWINGS

So that the manner in which the above-recited features of the present disclosure can be understood in detail, a more particular description of the embodiments, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic side view of a portion of a processing system, according to one embodiment.

FIG. 2 is a flow diagram for method operations of controlling conductance in a processing region of a processing chamber, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments provided herein generally relate to a processing system and a method of controlling conductance in a processing system. The processing system and method disclosed herein allow for control of gas ratios within the processing system, while still maintaining a high level of conductance. The processing system includes a purge gas valve configured to pulse a flow of foreline purge gas. The method includes pulsing the foreline purge gas. The method is contained in a computer readable medium. The pulsed foreline purge gas can maintain a ratio of process gas and process purge gas in the processing region. Increasing the conductance of the gas mixture including the process gas and the process purge gas results in more ALD-like behavior than undesired CVD behavior. Embodiments disclosed herein can be useful for, but are not limited to, a processing system with high gas conductance.

As used herein, the term “about” refers to a +/−25% variation from the nominal value. It is to be understood that such a variation can be included in any value provided herein.

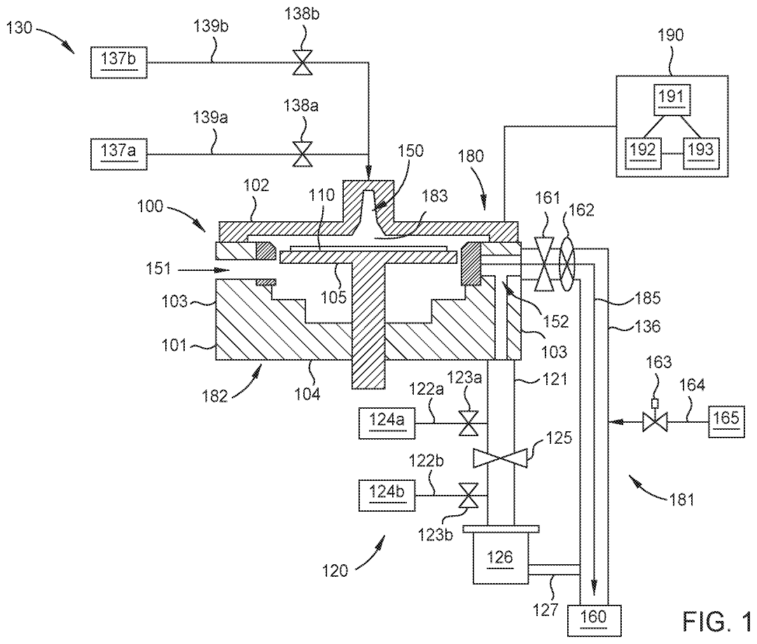

FIG. 1 illustrates a schematic side view of a portion of a processing system 100, according to one embodiment. The processing system 100 is configured to provide atomic layer deposition (ALD) on a substrate 110 disposed therein. As shown, the processing system 100 include a processing apparatus 180 and a controller 190. The processing system 100 can further include (not shown) any number of transfer chambers, additional processing chambers, load lock chambers, factory interfaces (FI), and the like.

As shown, the processing apparatus 180 includes a processing chamber 101, an intake system 130, an outtake system 181, and a secondary outtake system 120. As shown, the processing chamber 101 includes a chamber body 182 and a pedestal 105. The chamber body 182 includes a plurality of walls 103, a ceiling 102, and a floor 104. One or more of the plurality of walls 103 includes one or more slots 151. The slot 151 allows for movement of a substrate 110 in or out of the processing chamber 101. One of the walls 103 includes an exhaust channel 152. The exhaust channel 152 is fluidly coupled to the outtake system 181 and the secondary outtake system 120. The ceiling 102 includes an intake portal 150. The intake portal 150 is fluidly connected to the intake system 130.

A processing region 183 is defined by the volume enclosed by the chamber body 182. The pedestal 105 is disposed within the processing region 183. The pedestal 105 is configured to support the substrate 110. Other components, such as deposition rings, electrostatic chucks, vacuum chucks, shields, and the like are not shown in FIG. 1, but it is to be understood that the processing chamber 101 can include any other number of components used in a typical processing chamber.

The intake system 130 is configured to flow a process gas into the processing region 183 of the processing chamber 101. As shown, the intake system 130 includes a plurality of process gas sources 137a, 137b, a plurality of process gas lines 139a, 139b, and a plurality of process gas valves 138a, 138b. Each of the plurality of process gas lines 139a, 139b is fluidly connected to the each of the plurality of process gas sources 137a, 137b and the intake portal 150. The process gas valves 138a, 138b are configured to open and close and control the flow of process gas through the process gas lines 139a, 139b.

The process gases include any precursor and/or reactant used in ALD. For example, the precursor and/or reactant includes titanium chloride (TiCl), tantalum chloride (TaCl), tungsten chloride (WCl), hafnium chloride (HfCl), molybdenum chloride (MoCl), other metal chlorides, water, hydrogen gas (H₂), ammonia (NH₃), and any combination of the above. In some embodiments, the process gas also includes a carrier gas. For example, the carrier gas includes an inert gas, argon (Ar), nitrogen gas (N₂), or any combination of the above. In some embodiments that can be combined with any of the embodiments described above, the process gas also includes a process purge gas. For example, the process purge gas includes any neutral gas used in ALD, N₂, Ar, or any combination thereof.

Although only two process gas sources 137a, 137b and corresponding process gas lines 139a, 139b and process gas valves 138a, 138b are shown, it is to be understood that any number of process gas sources 137, process gas lines 139, and process gas valves 138 can be included.

The outtake system 181 is configured to flow ALD byproducts from the processing region 183 through the outtake system (flow of ALD byproducts indicated by 185). As shown, the outtake system 181 includes an output pump 160, a foreline 136, a foreline valve 161, a throttle valve 162, a purge gas source 165, a purge gas line 164, and a purge gas valve 163.

The foreline valve 161 is configured to open and close, which allows for stopping and starting the flow of the ALD byproducts. The foreline 136 delivers a foreline purge gas to the exhaust channel 152. The pumping conductance of the outtake system 181 is increased by increasing the diameter of the foreline 136. The increased size of the foreline 136 improves pumping conductance to over about 60% compared to traditional outtake systems. Increasing the conductance of the gas mixture including the ALD byproducts and the foreline purge gas results in more ALD-like behavior than undesired chemical vapor deposition (CVD) behavior. The increased gas conductance also increases byproduct flow through the outtake system 181.

The purge gas line 164 is fluidly coupled to the foreline 136. The purge gas source 165 is fluidly coupled to the purge gas line 164. The purge gas source 165 is configured to flow the foreline purge gas through the purge gas line 164 and the foreline 136. The purge gas valve 163 is disposed in the purge gas line 164. The foreline purge gas can include any neutral gas used in ALD. The foreline purge gas includes nitrogen gas (N₂), argon, or any combination thereof, according to some embodiments.

The purge gas valve 163 is configured to either allow a constant flow of the foreline purge gas, or to alternately open and close, which pulses the flow of foreline purge gas. The purge gas valve 163 can alternately open and close at a rate of about 0.02 s to about 5 min, such as about 0.02 s to about 0.1 s. The purge gas valve 163 is configured to alternately open and close at about the rate of the ALD pulse and purge rate. The purge gas valve 163 is configured to alternately open at the ALD pulse step and to close at the ALD purge step. The purge gas valve 163 is configured to increase the pressure of the foreline by up to about 10 Torr, such as by about 5 Torr.

The pressure in the processing region 183 is increased by pulsing the foreline purge gas into the foreline 136 either during a pulse or purge step while a gas ratio between the process gas and the process purge gas in the processing region 183 remains about constant, according to one embodiment. The increased foreline purge gas flow during the purge step increases the foreline 136 pressure.

The foreline valve 161 and the throttle valve 162 are disposed in the foreline 136. The foreline valve 161 is configured to isolate the processing chamber 101 from the output pump 160. The throttle valve 162 is configured to control the process pressure in the processing region 183.

The secondary outtake system 120 is configured to lower the pressure of the processing region 183 during wafer exchange. In addition, the secondary outtake system 120 is configured to pump out any residual gas not pumped out by the outtake system 181. As shown, the secondary outtake system 120 includes a gas outtake line 121, a gas outtake valve 125, one or more gas leak lines 122, one or more leak valves 123, a vacuum pump 126, one or more sensors 124, and a vacuum outtake 127. The gas outtake line 121 is fluidly coupled to the exhaust channel 152. The gas outtake valve 125 is disposed in the gas outtake line 121.

The vacuum pump 126 is fluidly coupled to the gas outtake line 121. The vacuum pump 126 can be a turbo pump. The one or more gas leak lines 122 are fluidly coupled to the gas outtake line 121. The one or more leak valves 123 are disposed in the one or more gas leak lines 122. The one or more sensors 124 are fluidly coupled to the one or more gas leak lines 122 via the one or more leak valves 123.

The one or more leak valves 123 are configured to control the flow of residual gas or other present gas through the secondary outtake system 120. The one or more leak valves 123 can include isolation valves. The one or more sensors 124 can include any sensor used in monitoring gas flow, such as moisture sensors, oxygen gas (02) sensors, and/or leak sensors. The one or more sensors 124 are configured to measure processing variables, such as moisture and/or 02 levels, which allows the user to identify if leaks are present in the processing apparatus. The one or more sensors 124 are configured to measure processing variables either while the processing apparatus 180 is in use, or when the processing apparatus 180 is not in use. For example, the sensor 124a is configured to measure processing variables while the processing apparatus 180 is not in use. For example, the sensor 124b is configured to measure processing variables while the processing apparatus 180 is in use.

The one or more gas leak lines 122 include two gas leak lines, the one or more leak valves 123 include two leak valves, and the one or more sensors 124 include two sensors, according to one embodiment. As shown, a first set of gas leak line 122a, leak valve 123a, and sensor 124a is disposed on one side of the gas outtake valve 125 (i.e., upstream of the gas outtake valve 125), and a second set of gas leak line 122b, leak valve 123b, and sensor 124b is disposed on the other side of the gas outtake valve 125 (i.e., downstream of the gas outtake valve 125). Placement of the sensors 124 in this manner allow for a more accurate location of where any leaks are present in the secondary outtake system 120. However, other arrangements of the gas leak lines 122, leak valves 123, and sensors 124 are contemplated.

The controller 190 is configured to control various components of the processing system 100. As shown, the controller 190 includes a programmable central processing unit (CPU) 191, a memory (e.g., non-volatile memory) 192, and support circuits 193. The support circuits 193 are conventionally coupled to the CPU 191 and comprise cache, clock circuits, input/output subsystems, power supplies, and the like, and combinations thereof coupled to the various components of the processing system 100, to facilitate control thereof. The CPU 191 is one of any form of general purpose computer processor used in an industrial setting, such as a programmable logic controller (PLC), for controlling various components and sub-processors of the processing system 100. The memory 192, coupled to the CPU 191, is non-transitory and is typically one or more of readily available memories such as random access memory (RAM), read only memory (ROM), floppy disk drive, hard disk, or any other form of digital storage, local or remote.

Typically, the memory 192 is in the form of a computer-readable storage media containing instructions (e.g., non-volatile memory), which when executed by the CPU 191, facilitates the operation of the processing system 100. The instructions in the memory 192 are in the form of a program product such as a program that implements the methods of the present disclosure.

The program code can conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as compact disc-read only memory (CD-ROM) disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the methods set forth herein are performed by a combination of software routines, ASIC(s), FPGAs and, or, other types of hardware implementations.

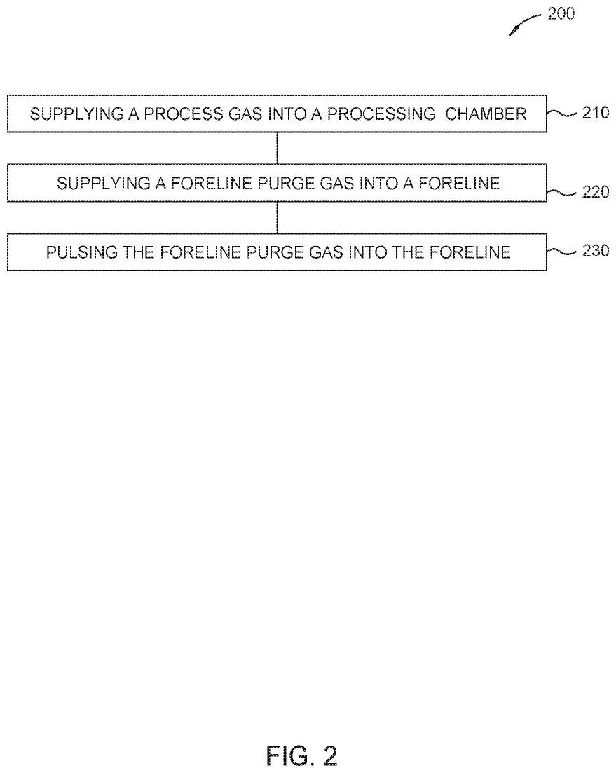

FIG. 2 is a flow diagram for method 200 operations of controlling conductance in a processing region of a processing chamber (e.g., processing region 183 of processing chamber 101), according to one embodiment. Although the method 200 operations are described in conjunction with FIGS. 1 and 2, persons skilled in the art will understand that any system configured to perform the method operations, in any order, falls within the scope of the embodiments described herein. Embodiments of the method 200 can be used in combination with one or more of the systems and system operations described herein, such as the processing system 100 of FIG. 1. The method 200 can be stored or accessible to the controller 190 as computer readable media containing instructions, that when executed by the CPU 191, cause the processing system 100 to perform the method 200.

The method 200 begins at operation 210, where a process gas is supplied into the processing chamber 101 through a process gas line (e.g., process gas line 139). For example, the process gas is flowed through a process gas line of an intake system (e.g., intake system 130).

At operation 220, a foreline purge gas is flowed through the foreline 136.

At operation 230, the foreline purge gas is pulsed into the foreline 136. For example, a purge gas valve (e.g., purge gas valve 163) is configured to either allow a constant flow of the process gas, or to alternately open and close, which pulses the flow of foreline purge gas. The purge gas valve 163 can alternately open and close at a rate of about 0.02 s to about 5 min, such as about 0.02 s to about 0.1 s. The pressure in the processing region 183 is increased by pulsing the foreline purge gas into the foreline 136 either during a pulse or purge step while a gas ratio between the process gas and a process purge gas in the processing region 183 remains about constant, according to one embodiment.

Some ALD processes require high pressure pulses and low pressure purge, for a certain mix of process gas and purge flow. High pressure pulse can be achieved by adding more process purge gas to the total flow, but the high pressure pulse dilutes and decreases a gas ratio between the precursor gas and the process purge gas. However, operation 230, as described above, can maintain the desired gas ratio by producing a high pressure pulse of the foreline purge gas. In some embodiments, a high pressure pulse is followed by a low pressure purge, and then followed by a high pressure purge. The pressure of the high pressure purge can be the same or different from the pressure of the high pressure pulse

As described above, a processing system, a computer readable medium, and a method of controlling conductance in a processing region of a processing chamber of the processing system is provided. The processing system includes a purge gas valve configured to pulse a flow of foreline purge gas. The method includes pulsing the foreline purge gas. The method is contained in a computer readable medium. The pressure in the processing chamber is increased by opening the foreline purge gas valve during the pulse step, and the pressure in the processing chamber is reduced during the purge step by closing the foreline purge gas valve.

The pulsed foreline purge gas can maintain a ratio of the process gas and the process purge gas in the processing region. Increasing the conductance of the gas mixture including the process gas and the process purge gas results in more ALD-like behavior than undesired CVD behavior. The increased conductance in the foreline also allows for higher flow of process and process purge gases, increasing the throughput of film growth on substrates for the user.

While the foregoing is directed to implementations of the present invention, other and further implementations of the invention may be devised without departing from the basic scope thereof, and the scope thereof is determined by the claims that follow.

1. A method of controlling conductance in a processing region of a processing chamber, the method comprising:
supplying a process gas into the processing chamber;
supplying a foreline purge gas into a foreline; and
pulsing the foreline purge gas into the foreline.

2. The method of claim 1, wherein the pulsing the foreline purge gas comprises:
alternately opening and closing a purge gas valve fluidly connected to the foreline, the alternately opening and closing the purge gas valve occurring at a rate of about 0.02 s to about 5 min.

3. The method of claim 1, wherein the foreline purge gas comprises nitrogen gas (N₂) and argon (Ar).

4. The method of claim 1, wherein, during the pulsing the foreline purge gas, a gas ratio between the process gas and a process purge gas in the processing region remains about constant.

5. A processing system, comprising:
a processing apparatus, comprising:
a processing chamber comprising a chamber body defining a processing region; and
an outtake system comprising:
a foreline fluidly coupled to the chamber body;
a purge gas line fluidly coupled to the foreline;
a purge gas source fluidly coupled to the purge gas line; and
a purge gas valve disposed in the purge gas line; and
a controller coupled to the purge gas valve, the controller configured to perform a method of controlling conductance in the processing region of the processing chamber, the method comprising:
supplying a process gas into the processing chamber;
supplying a foreline purge gas into the foreline; and
pulsing the foreline purge gas into the foreline, the pulsing the foreline purge gas comprising:
alternately opening and closing the purge gas valve.

6. The processing system of claim 5, wherein the alternately opening and closing the purge gas valve occurs at a rate of about 0.02 s to about 5 min.

7. The processing system of claim 5, wherein the foreline purge gas comprises nitrogen gas (N₂) or argon (Ar).

8. The processing system of claim 5, wherein, during the pulsing the foreline purge gas, a gas ratio between the process gas and a process purge gas in the processing region remains about constant.

9. The processing system of claim 5, wherein the processing system further comprises a secondary outtake system, comprising:
a gas outtake line fluidly coupled to the chamber body;
one or more gas leak lines fluidly coupled to the gas outtake line; and
one or more leak valves disposed in the one or more gas leak lines.

10. The processing system of claim 9, wherein the secondary outtake system further comprises one or more sensors fluidly coupled to the one or more gas leak lines.

11. The processing system of claim 9, wherein the secondary outtake system further comprises a vacuum pump fluidly coupled to the gas outtake line.

12. The processing system of claim 11, wherein:
the one or more gas leak lines include two gas leak lines, and the one or more leak valves include two leak valves.

13. A non-transient computer readable medium containing program instructions for causing a controller to perform a method comprising:
supplying a process gas into a processing region of a processing chamber;
supplying a foreline purge gas into a foreline; and
pulsing the foreline purge gas into the foreline.

14. The non-transient computer readable medium of claim 13, wherein the pulsing the foreline purge gas comprises:
alternately opening and closing a purge gas valve fluidly connected to the foreline, the alternately opening and closing the purge gas valve occurring at a rate of about 0.02 s to about 5 min.

15. The non-transient computer readable medium of claim 13, wherein the foreline purge gas comprises nitrogen gas (N₂) or argon (Ar).

16. The non-transient computer readable medium of claim 13, wherein, during the pulsing the foreline purge gas, a gas ratio between the process gas and a process purge gas in the processing region remains about constant.

17. The non-transient computer readable medium of claim 13, wherein the controller is coupled to a processing apparatus comprising:
the processing chamber comprising a chamber body defining the processing region; and
an outtake system comprising:
the foreline fluidly coupled to the chamber body;
a purge gas line fluidly coupled to the foreline;
a purge gas source fluidly coupled to the purge gas line; and
a purge gas valve disposed in the purge gas line.

18. The non-transient computer readable medium of claim 17, wherein the processing system further comprises a secondary outtake system, comprising:
a gas outtake line fluidly coupled to the chamber body;
one or more gas leak lines fluidly coupled to the gas outtake line; and
one or more leak valves disposed in the one or more gas leak lines.

19. The non-transient computer readable medium of claim 18, wherein the secondary outtake system further comprises one or more sensors fluidly coupled to the one or more gas leak lines.

20. The non-transient computer readable medium of claim 18, wherein the secondary outtake system further comprises a vacuum pump fluidly coupled to the gas outtake line.
